(19) United States
(12) Patent Application Publication
(10) Pub. No.: US 2014/0035461 A1
(43) Pub. Date: Feb. 6, 2014

(54) HIGH-BAY LIGHTING

(71) Applicants: Edward E. McDonald, Gilbert, AZ (US); Stuart W. Rayburn, Phoenix, AZ (US)

(72) Inventors: Edward E. McDonald, Gilbert, AZ (US); Stuart W. Rayburn, Phoenix, AZ (US)

(73) Assignee: MCDOWELL 78 LLC, Tempe, AZ (US)

(21) Appl. No.: 13/566,233

(22) Filed: Aug. 3, 2012

(51) Int. Cl. H05B 33/02; H05K 13/00; H05B 33/08

(52) U.S. Cl. 315/113; 313/114; 313/46; 313/111; 29/592.1

(57) ABSTRACT

Exemplary embodiments are directed to methods, system, and devices for high-bay lighting. A device may comprise a plurality of reflectors coupled to a support structure. The device may further include a plurality of light emitting diodes (LEDs), wherein each LED of the plurality of LEDs is coupled to and positioned within a dedicated reflector of the plurality of reflectors.

### BACKGROUND

1. Field

The present invention relates generally to high-bay lighting. More specifically, the present invention relates to high-bay lighting methods, devices, and systems including one or more light emitting diodes.

2. Background

High bay lighting devices may be used indoor where the ceiling height is relatively high (e.g., greater than 20 feet). Accordingly, high-bay lighting systems may be ideal for lighting warehouses, large retails stores, manufacturing facilities, gymnasiums, and hangars. Further, high-bay lighting systems may also be utilized outdoor, such as for lighting athletic fields, parking lots, and roadways. Conventionally, high-bay lighting systems include either a high-intensity discharge (HID) light source, such as metal halide and high-pressure sodium lamps, or a high-intensity fluorescent (HIF) light source.

FIG. 1 illustrates a conventional high-bay lighting system 100. As illustrated, high-bay lighting system 100 includes a halide lamp 102 and a lighting fixture 104, which may also be referred to as a “parabolic reflector.” By way of example, halide lamp 102 may comprise a 250-1500 watt halide lamp. As will be appreciated by a person having ordinary skill in the art, costs associated with halide lamps, such as halide lamp 102, may be substantial. Further, light distribution, light output consistency, color, and overall lighting quality of halide lamps are not ideal.

A need exists to enhance high-bay lighting devices, systems, and methods. More specifically, a need exists for improving high-bay lighting quality while reducing associated costs.

### BRIEF DESCRIPTION OF THE DRAWINGS

FIG. 1 depicts a conventional high-bay lighting device including a halide lamp.

FIG. 2 illustrates a lighting device including a reflector and a light emitting diode, according to an exemplary embodiment of the present invention.

FIG. 3A illustrates another lighting device including a reflector and a light emitting diode, in accordance with an exemplary embodiment of the present invention.

FIG. 3B is another illustration of the lighting device of FIG. 3A.

FIG. 4 illustrates a lighting system including a lighting apparatus coupled to a support structure, in accordance with an exemplary embodiment of the present invention.

FIG. 5 illustrates a lighting apparatus including a plurality of lighting devices coupled to a support structure, in accordance with an exemplary embodiment of the present invention.

FIG. 6 is another illustration of the lighting system of FIG. 5.

FIG. 7 illustrates a support structure configured for coupling to one or more lighting devices, according to an exemplary embodiment of the present invention.

FIG. 8 is an illustration of a support structure, in accordance with an exemplary embodiment of the present invention.

FIG. 9A depicts a lighting device having a lens coupled thereto, according to an exemplary embodiment of the present invention.

FIG. 9B is another illustration of a lighting device having a lens coupled thereto, in accordance with an exemplary embodiment of the present invention.

FIG. 10 illustrates a system including a lighting system positioned within a lighting fixture, according to an exemplary embodiment of the present invention.

FIG. 11 illustrates a system including a power source coupled to a lighting system, according to an exemplary embodiment of the present invention.

FIG. 12 illustrates a system including a plurality of lighting systems, in accordance with an exemplary embodiment of the present invention.

FIG. 13 is a flowchart illustrating a method, in accordance with an exemplary embodiment of the present invention.

FIG. 14 is a flowchart illustrating another method, in accordance with an exemplary embodiment of the present invention.

FIG. 15 is a flowchart illustrating yet another method, in accordance with an exemplary embodiment of the present invention.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

Referring in general to the accompanying drawings, various embodiments of the present invention are illustrated to show the structure and methods for a computer network security system. Common elements of the illustrated embodiments are designated with like numerals. It should be understood that the figures presented are not meant to be illustrative of actual views of any particular portion of the actual device structure, but are merely schematic representations which are employed to more clearly and fully depict embodiments of the invention.

The following provides a more detailed description of the present invention and various representative embodiments thereof. In this description, functions may be shown in block diagram form in order not to obscure the present invention in unnecessary detail. Additionally, block definitions and partitioning of logic between various blocks is exemplary of a specific implementation. It will be readily apparent to one of ordinary skill in the art that the present invention may be practiced by numerous other partitioning solutions. For the most part, details concerning timing considerations and the like have been omitted where such details are not necessary to obtain a complete understanding of the present invention and are within the abilities of persons of ordinary skill in the relevant art.

In this description, some drawings may illustrate signals as a single signal for clarity of presentation and description. It will be understood by a person of ordinary skill in the art that the signal may represent a bus of signals, wherein the bus may have a variety of bit widths and the present invention may be implemented on any number of data signals including a single data signal.

Exemplary embodiments, as described herein, are directed to a lighting apparatus including a plurality of high-energy light emitting diodes (LEDs) positioned proximate a support structure, which may comprise a heat sink. More specifically, each LED of the plurality of LEDs may be positioned within and secured to a dedicated reflector, which is secured to a surface of the support structure.

As one example, an apparatus may comprise a plurality of reflectors coupled to a support structure. The apparatus may further include a plurality of light emitting diodes (LEDs), wherein each LED of the plurality of LEDs are coupled to and positioned within a dedicated reflector of the plurality of reflectors. As another example, an apparatus may include a plurality of reflectors adjacent a heat sink. In addition, the apparatus may include a plurality of LEDs, wherein each reflector of the plurality of reflectors having an LED of the plurality of LEDs positioned thereon.

As yet another example, a system may comprise a lighting fixture having a lighting apparatus coupled thereto. The lighting apparatus may include a heat sink and a plurality of reflectors positioned on the heat sink. Furthermore, the lighting apparatus may include a plurality of LEDs, wherein each reflector of the plurality of reflectors has an LED of the plurality of LEDs positioned thereon. According to one exemplary embodiment, each LED may comprise a high-power LED, as described more fully below.

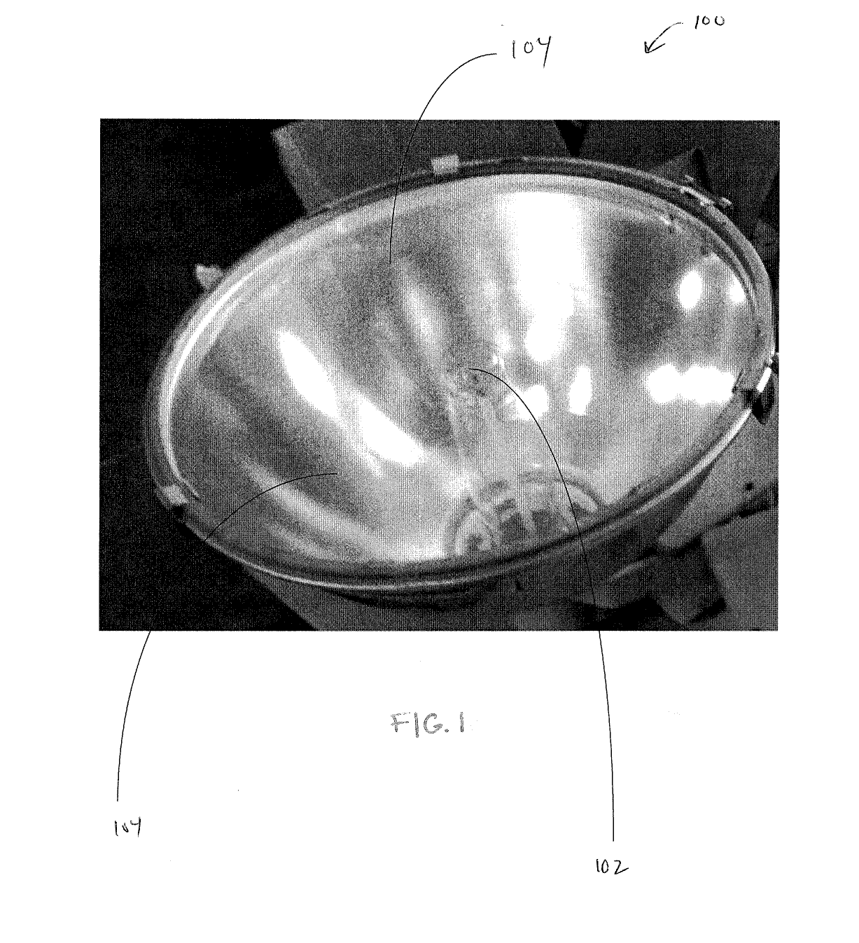

It is noted that the lighting apparatuses described herein may be retrofit to an existing lighting fixture. More specifically, according to one exemplary embodiment, a lighting apparatus may be retrofit to an existing lighting fixture, such as parabolic reflector 104 illustrated in FIG. 1. Further, other housing components of an existing lighting fixture may be reused. Other embodiments may include “new” fixtures, which may include, for example, a lighting fixture having a lighting apparatus coupled to a lighting fixture, such as a parabolic reflector. In addition, exemplary embodiments of the present invention may include an adjustable power supply, which may be dedicated to a lighting apparatus. As an example, exemplary embodiments described herein may be applicable for lighting applications in the range of substantially 400-1000 watts.

In comparison to conventional LED systems, which may use a large number (e.g., 40-60) of low-power LEDs for a specific application (e.g., 400 watt application), exemplary embodiments of the present invention may include a relatively small number (e.g., 5-15) of high-power LEDs for a similar application. Further, in contrast to a conventional system, exemplary embodiments of the present invention may include a dedicated reflector for each LED. In addition, rather than utilizing an active heat sink, which includes one or more moving parts, embodiments of the present invention include a passive heat sink, which may include a plurality of holes, a plurality of fingers, or both, for providing additional “edge area,” which aides in heat dissipation.

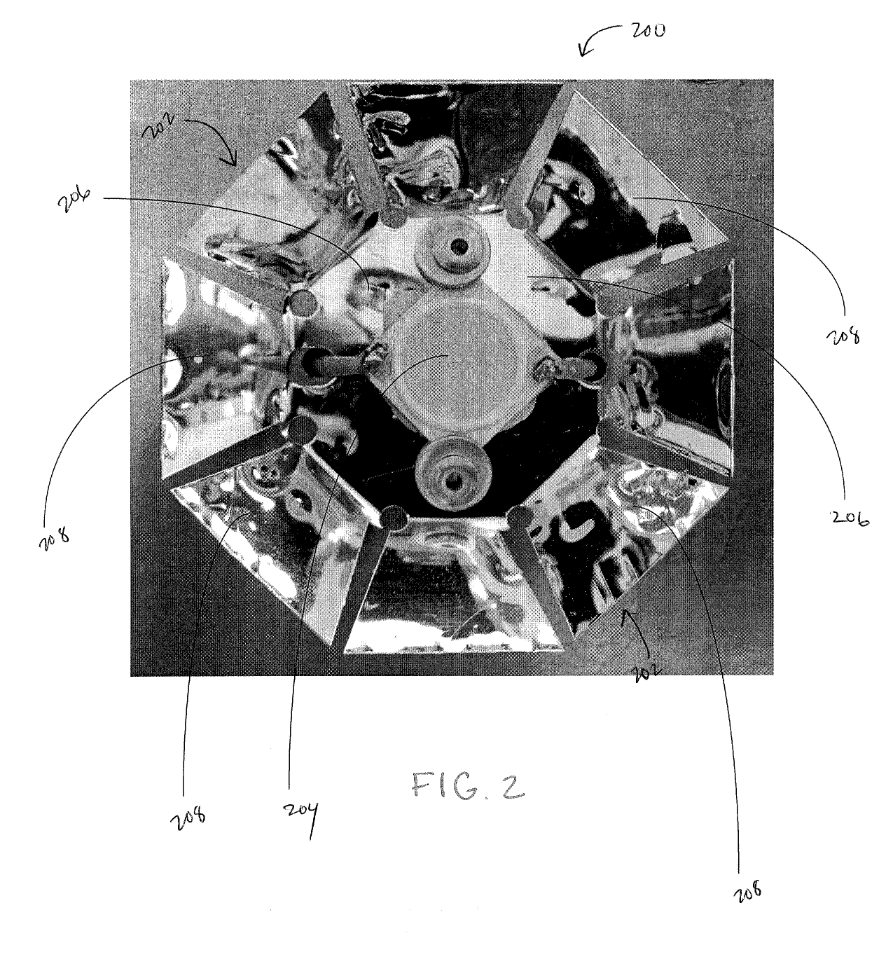

FIG. 2 illustrates a lighting device 200, according to an exemplary embodiment of the present invention. Lighting device 200 includes a reflector 202 and a light emitting diode (LED) 204. As illustrated, reflector 202 includes a base portion 206 and a plurality of independently adjustable sides 208. As will be appreciated by a person having ordinary skill in the art, each reflector 202 may be configured to change an angle of reflection of an associated LED. More specifically, one or more sides 208 of reflector 202 may be adjusted (e.g., during manufacturing of reflector 202) to the change the angle of reflection of the associated LED. As such, the configuration of a reflector 202 may be adjusted according to a desired lighting application (i.e., a lighting device 20 feet off the ground may likely have a different angle of reflection than a lighting device 60 feet off the ground). As one example, one or more reflectors 206 may be configured to provide a “spot light.” As another example, one or more reflectors 206 may be configured to provide a “flood light.”

Using adjustable reflectors, such as reflectors 206, may reduce the amount of energy required to provide light to a desired area and, thus, reflectors 206 may further increase an efficiency of a lighting device. For example only, exemplary embodiments of the present invention may provide substantially 120 degrees of lighting coverage using substantially 105-115 watts for a 400 watt metal halide equivalent. In contrast, lighting systems without reflectors (i.e., lighting systems that use lens based optics for directing light), which may require between 175-185 watts for a 400 watt metal halide equivalent, may not achieve 120 degrees of coverage. It is noted that, although reflector 206 is illustrated as including eight sides 208, the present invention is not so limited. Rather, reflector 206 may include any number of sides.

As noted above, LED 204 may comprise a high-power LED. LED 204 may include a high-power LED (HPLED), which may emit, as a non-limiting example, more than 95 lumens per watt. As one example, LED 204 may emit substantially 138 lumens per watt. As another example, LED 204 may emit substantially 150 lumens per watt. For example, LED 208 may comprise a 26.4 Watt CITIZEN LED having part number CLL030-1212A1-50KL1A1 and having a maximum power of 64.2 Watts. As another non-limiting example, LED 208 may comprise a 17.6 Watt CITIZEN LED having part number CLL030-1208A1-50KL1A1 and having a maximum power of 42.8 Watts.

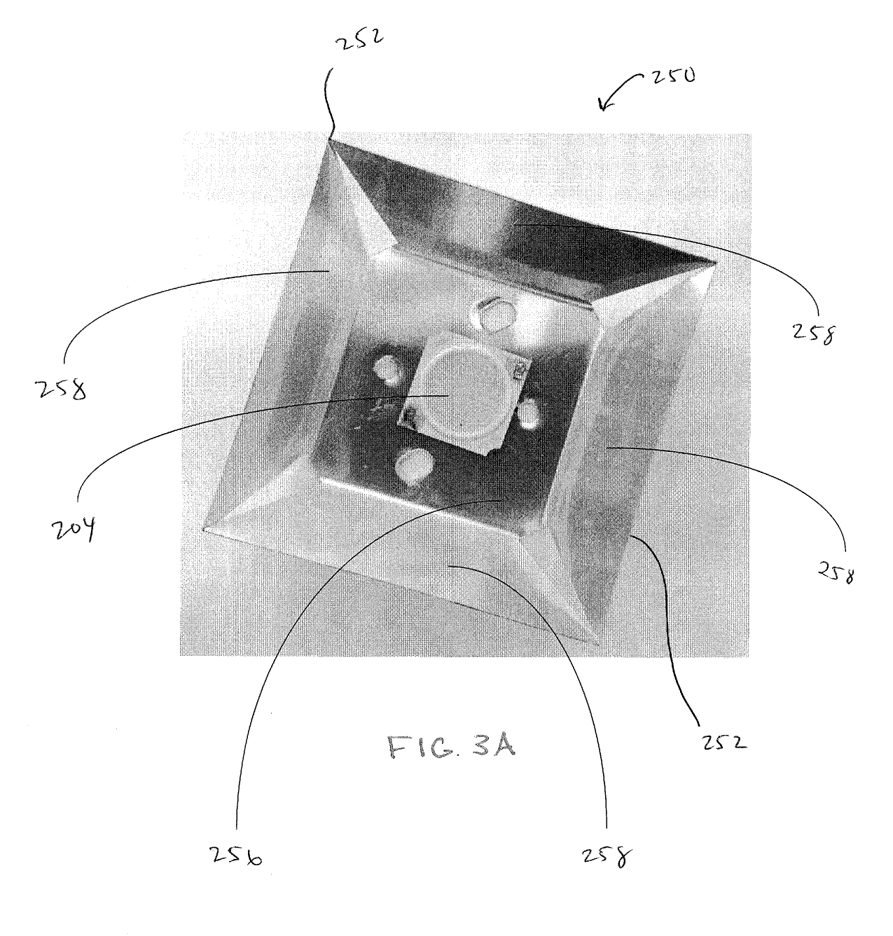

FIG. 3A depicts another example of a lighting device 250, according to an exemplary embodiment of the present invention. Lighting device 250 includes LED 204 and a reflector 252. Reflector 252 includes a base portion 256 and a plurality of sides 258. Similar to reflector 206, one or more sides 258 of reflector 252 may be adjusted to the change the angle of reflection of lighting device 250. Therefore, the configuration of a reflector 252 may be adjusted according to a desired lighting application. FIG. 3B is another illustration of lighting device 250.

FIG. 4 illustrates a lighting apparatus 300 including a plurality of lighting devices 200, in accordance with an exemplary embodiment of the present invention. It is noted that lighting although lighting apparatus 300 is illustrated as including lighting devices 200, lighting apparatus 300 may include lighting devices 250 illustrated in FIGS. 3A and 3B. Each lighting device 200 may be coupled to a support structure 302.

FIG. 5 is another, more detailed illustration of apparatus 300. As illustrated in

FIG. 5, apparatus 300 includes a plurality of lighting devices 200 coupled to support structure 302. According to one exemplary embodiment, lighting devices 200 may be uniformly spaced across a surface of support structure 302. FIG. 6 is yet another depiction of apparatus 300 including lighting devices 200 and support structure 302. FIG. 7 is a side-view of apparatus 300 including lighting devices 200 and support structure 302.

As will be understood by a person having ordinary skill in the art, a metal halide lighting device may handle heat much better than an LED device. Therefore, replacing a 1000 watt metal halide lamp with a 275 watt LED is substantially challenging in relation to heat control and LEDs may fail if heat is not adequately dissipated. As previously noted, support structure may comprise a heat sink configured for dissipating heat generated by one or more lighting devices coupled thereto. Support structure 302 may include a metal material, such as, for example only, aluminum. Support structure 302 may comprise a first portion 410 including a first outer surface 402 having one or more lighting devices positioned thereon. Support structure 202 may also include a second portion 420 (see FIG. 7), which is opposite to first portion 410. As illustrated in FIGS. 5 and 6, support structure 302 may comprise plurality of holes 400 through a surface 402 of support structure 302. In addition, surface 402 may include a plurality of “fingers” 404 proximate an outer edge of surface 402.

In addition, support structure 302 may include a central portion 430 positioned between first portion 410 and second portion 420. According to one exemplary embodiment, central portion 430 may comprise a plurality of stand-offs 440. Each stand-off 440 may be coupled to the first portion 410 and the second portion 420, and may further include a plurality of holes 400 and a plurality of fingers 404. Central portion, including stand-offs 440, may provide support for first portion 410 and second portion 420, as well as provide addition “edge area” for heat dissipation. According to one exemplary embodiment, a surface of each stand-off 440 including holes 400 may be perpendicular to a surface of the stand-off 440 that includes fingers 404. According to one exemplary embodiment, support structure 302 may include 16 stand-offs 440. However, any number of stand-offs is within the scope of the present invention.

As will be appreciated by a person having ordinary skill, holes 400 and fingers 404 create “edge area” that may assist in heat dissipation. Further, holes 400 may increase air flow through lighting apparatus 300 and, thus, may further assist in dissipation of heat generated by one or more lighting devices 200. It is noted that the position and size of holes 400 and fingers 404 may vary according to a desired application. A number of holes 400 and fingers 404 may also vary according to a desired application. As will be appreciated by a person having ordinary skill, in comparison to an active heat sink, which may include one or more moving parts (e.g. a fan), support structure 202 comprises a passive heat sink.

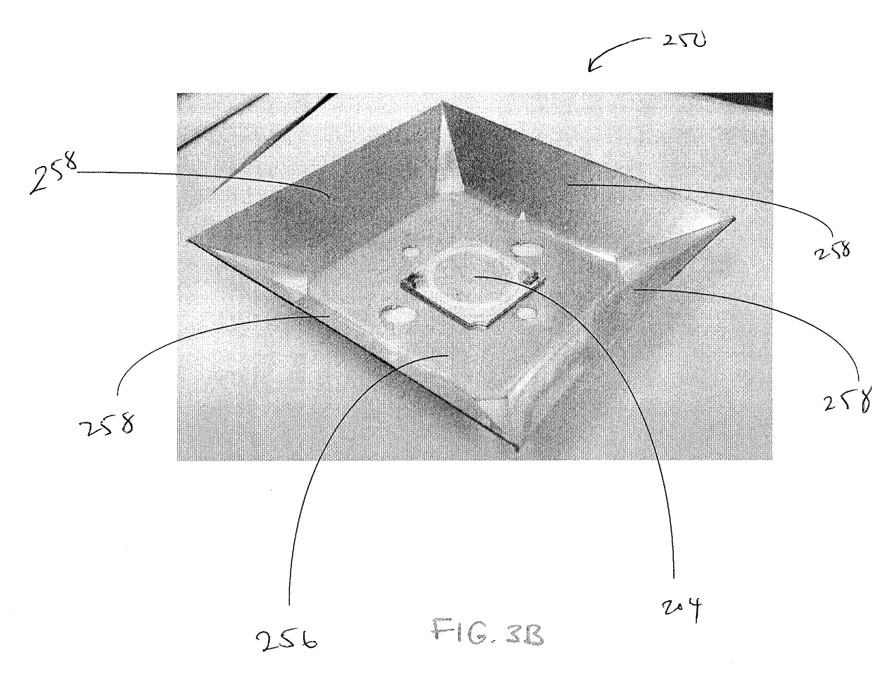

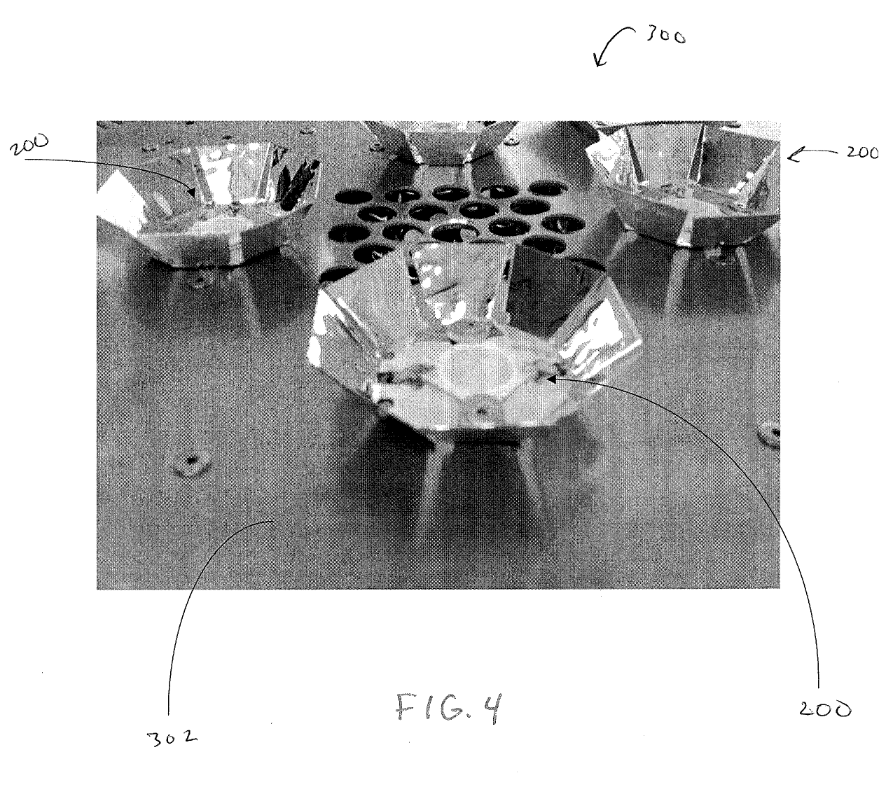

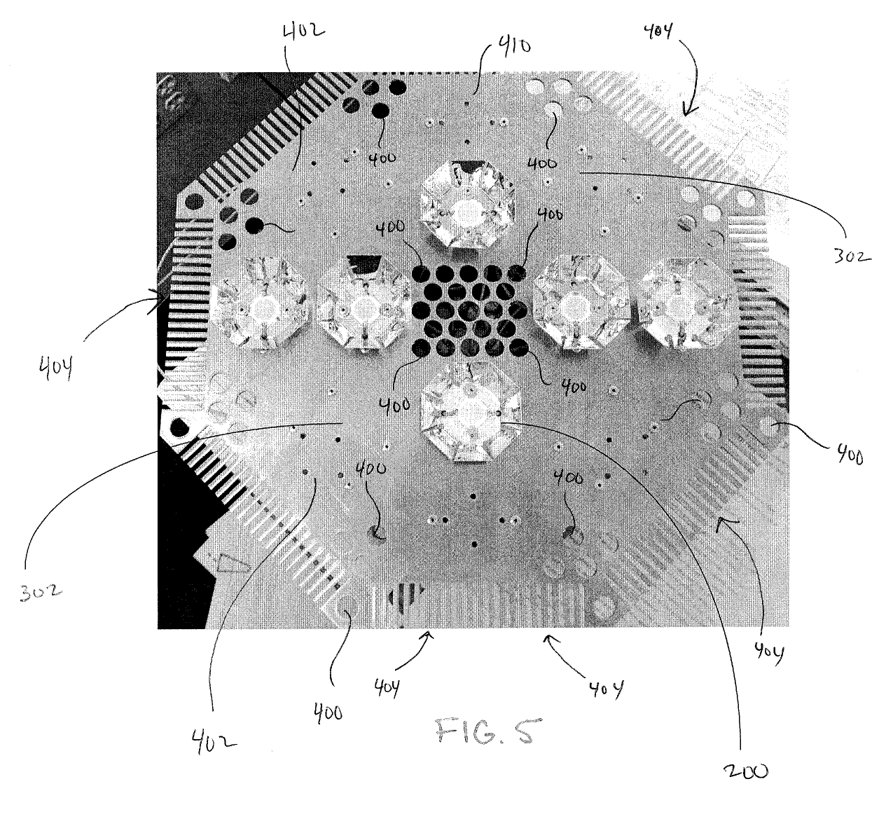

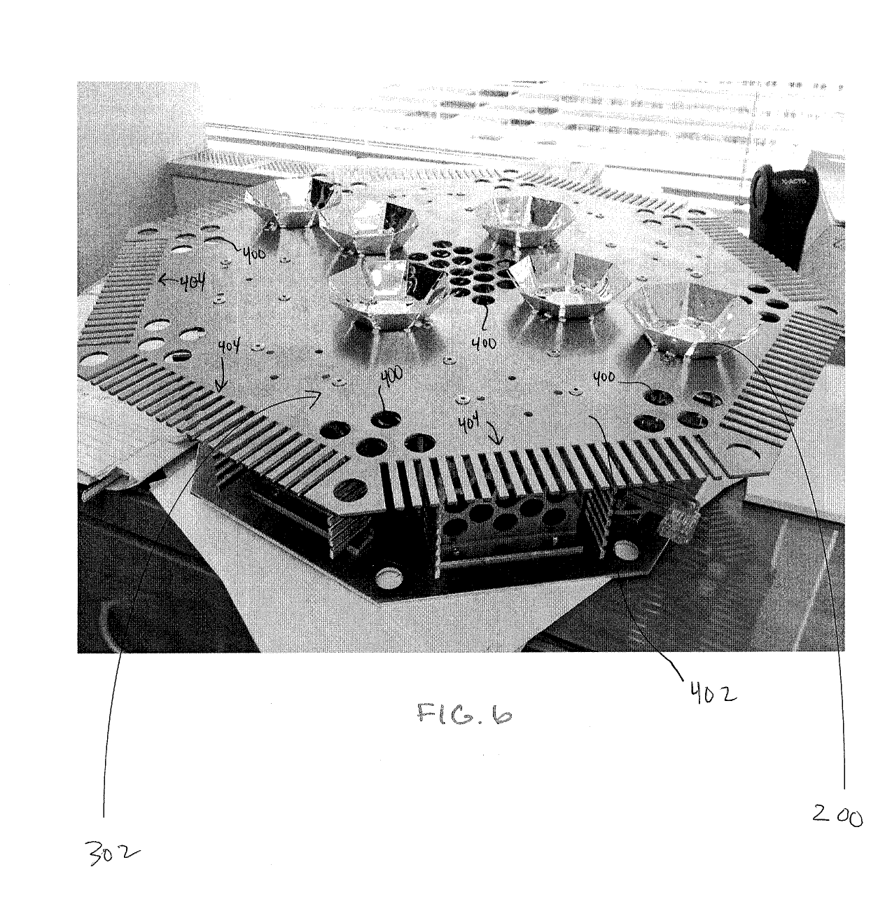

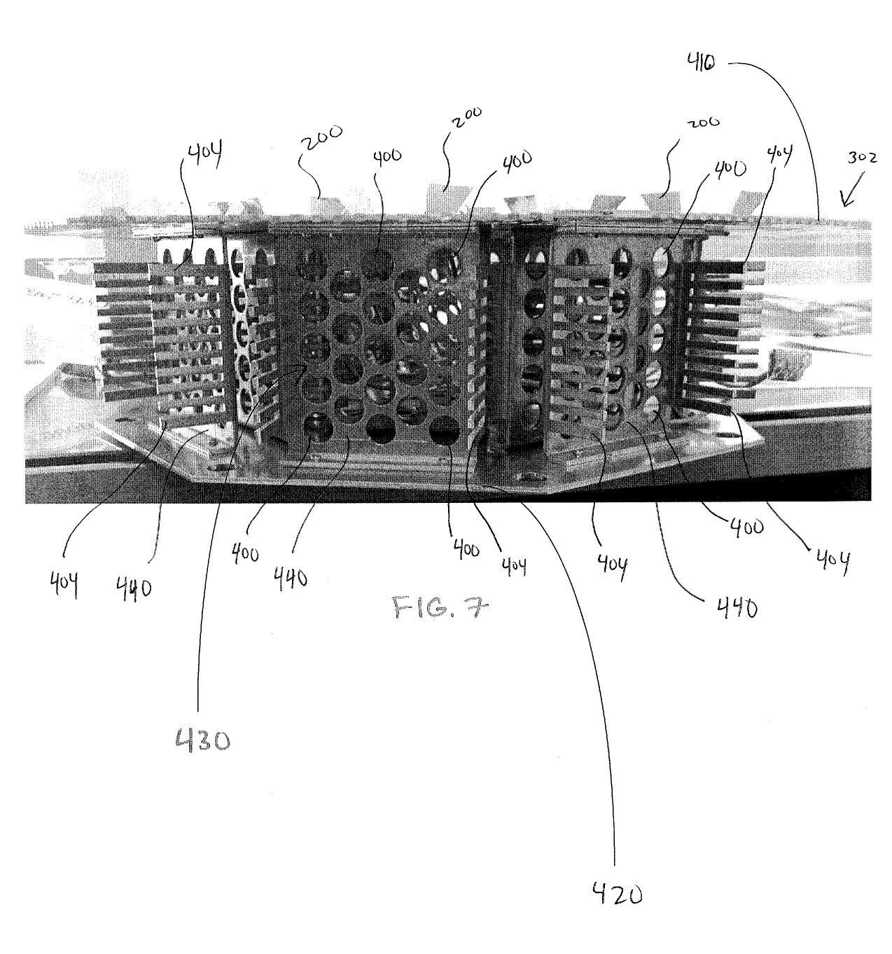

FIG. 8 is another view of support structure 302 including an external surface 450 of second portion 420. As illustrated surface 450 includes a plurality of holes 400. FIG. 8 also provides another view of central portion 430 including stand-offs 440.

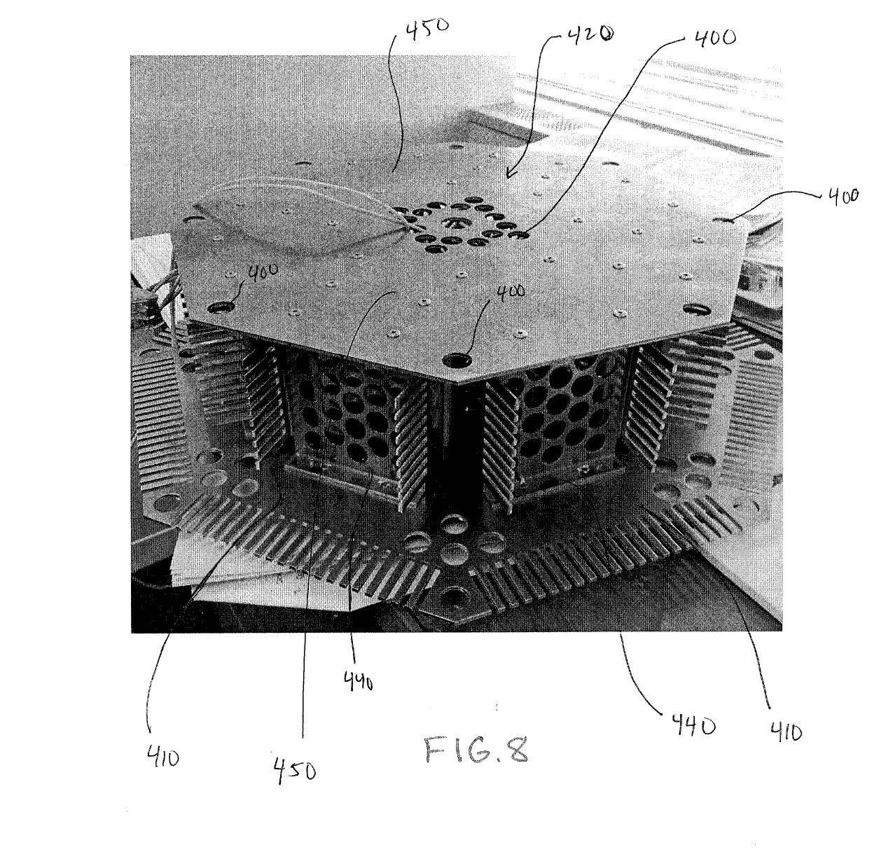

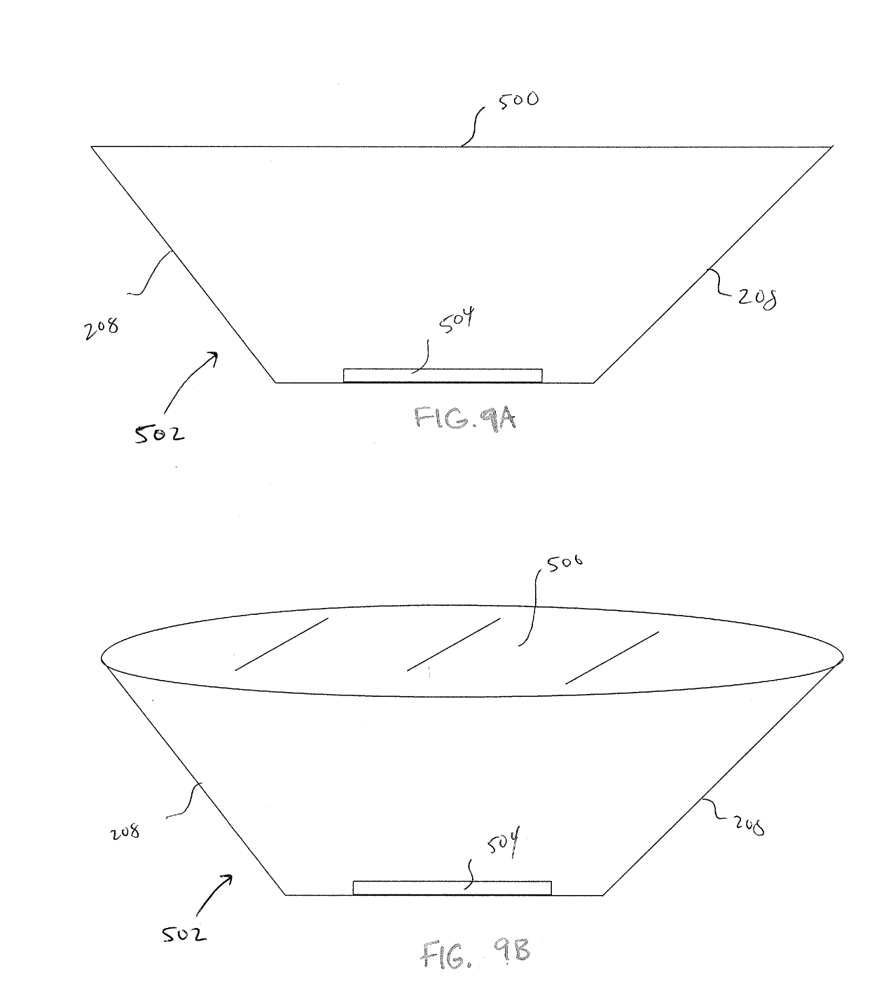

FIGS. 9A and 9B illustrate a lens 500 coupled to lighting device 502, in accordance with an exemplary embodiment of the present invention. Lighting device 502 may comprise for example only, lighting device 200 illustrated in FIG. 2 or lighting device 250 illustrated in FIGS. 3A and 3B. As depicted in FIGS. 9A and 9B, lens 500, which may comprise a material transparent to light (e.g., glass or plastic), may be configured to cover an LED, which may comprise LED 208 illustrated in FIGS. 2, 3A, and 3B. As such, according to one exemplary embodiment, each LED may have a dedicated lens 500, which may cover and protect the LED. In contrast to a configuration wherein a lens covers a plurality of LEDs, covering each LED with a dedicated lens may improve air-flow for a lighting system and, thus, heat dissipation for the lighting system may be improved.

According to one exemplary embodiment, lens 500 may be configured to protect an associated LED without providing for control of light spread (i.e., does not bend light traveling therethrough). According to another embodiment, in addition to providing protection for an associated LED, lens 500 may be configured for controlling the light spread distribution of the associated LED.

FIG. 10 illustrates a lighting system 550 including lighting apparatus 300 coupled to a lighting fixture 552, which may comprise lighting fixture 104 illustrated in FIG. 1. Accordingly, lighting apparatus 300 may be retrofit to an existing lighting fixture (e.g., a parabolic reflector). As illustrated in FIG. 10, lighting apparatus 300 includes a plurality of lighting devices 200 uniformly spaced across a surface of support structure 302. In accordance with one exemplary embodiment, a transparent lens (not shown in FIG. 10) may couple to lighting device 552, and thus may protect apparatus 300 from the environment, control light spread distribution associated with lighting apparatus 300, or both.

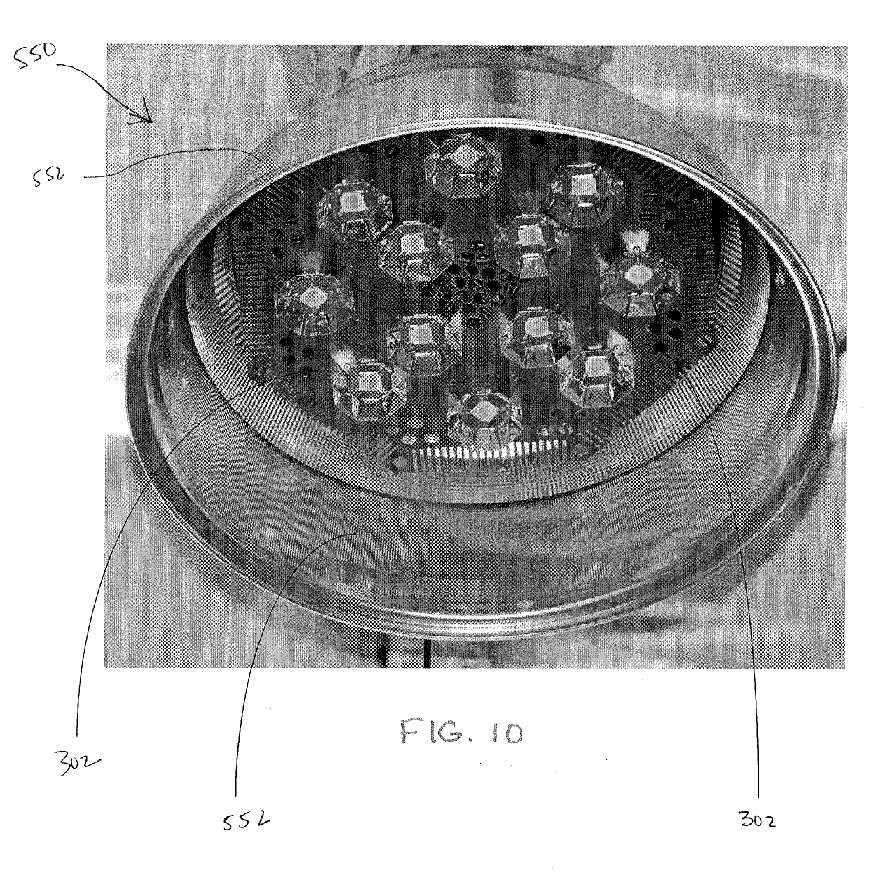

FIG. 11 illustrates a system 560 including 550 lighting system coupled to a power 570 supply, according to an exemplary embodiment of the present invention. According to one exemplary embodiment, power supply 570 may be configured to drive a high output chip of lighting system 550, such as a high-power LED (HPLED), as described above. For example only, power supply 570 may be configured to provide a voltage of more than 24 volts. According to another exemplary embodiment, power supply 570 may be adjustable (e.g., via wireless communication). As an example, power supply 570 may be adjustably configured to operate between substantially 80 watts to substantially 400 watts. In accordance with one exemplary embodiment, power supply 570 may have a “top-end” voltage and, may operated in a range, which is scaled back from the top-end voltage. For example, if power supply 570 has a top-end voltage of 51 volts, power supply 570 may operated in the range of substantially 35-48 volts. Actual voltage numbers may vary based on power supply 570 and diode combination of a lighting system. Further, power supply combinations may be used to cover different operating ranges, and, for each combination, there may be a limit on the low end of voltage adjustment for diode operation.

An adjustable power supply may be advantageous for many reasons. As one example, if it is desirable to raise a lighting system (i.e., a lighting system including one or more lighting systems 550) to a higher elevation, an amount of power supplied by power supply 570 may be increased to increase an intensity of the light projected by the lighting system. Similarly, an amount of power supplied by power supply 570 may be decreased to decrease an intensity of the light projected by the lighting system when the lighting system is lowered. As another example, power supply 570 may enable the lighting system to either dim or brighten associated LEDs depending on a location of the lighting system, a time of day, or both.

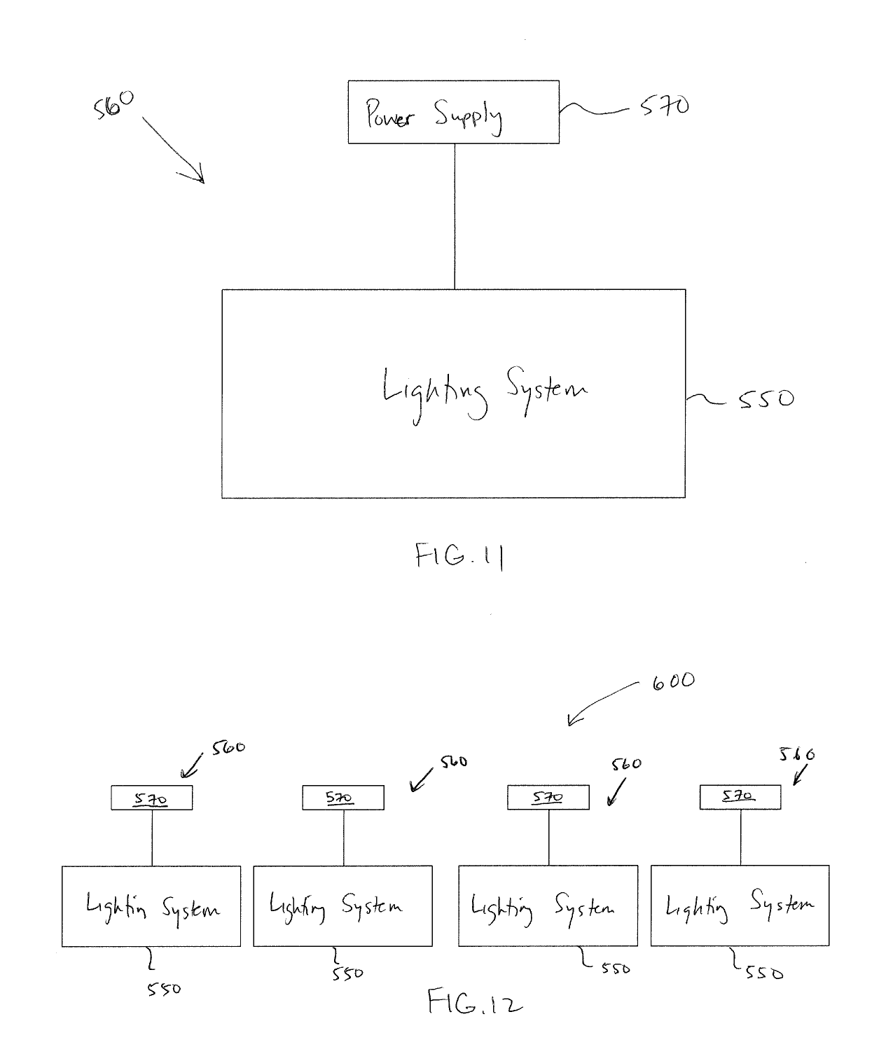

FIG. 12 illustrates a system 600 including a plurality of systems 560 wherein each system 560 includes a lighting system 550 coupled to a power supply. System 600 may be implemented in indoor venues, such as, for example only, warehouses, large retail stores, manufacturing facilities, and gymnasiums. Further, system 600 may also be utilized outdoor, such as, for example only, at an athletic field, a parking lot, or on a roadway.

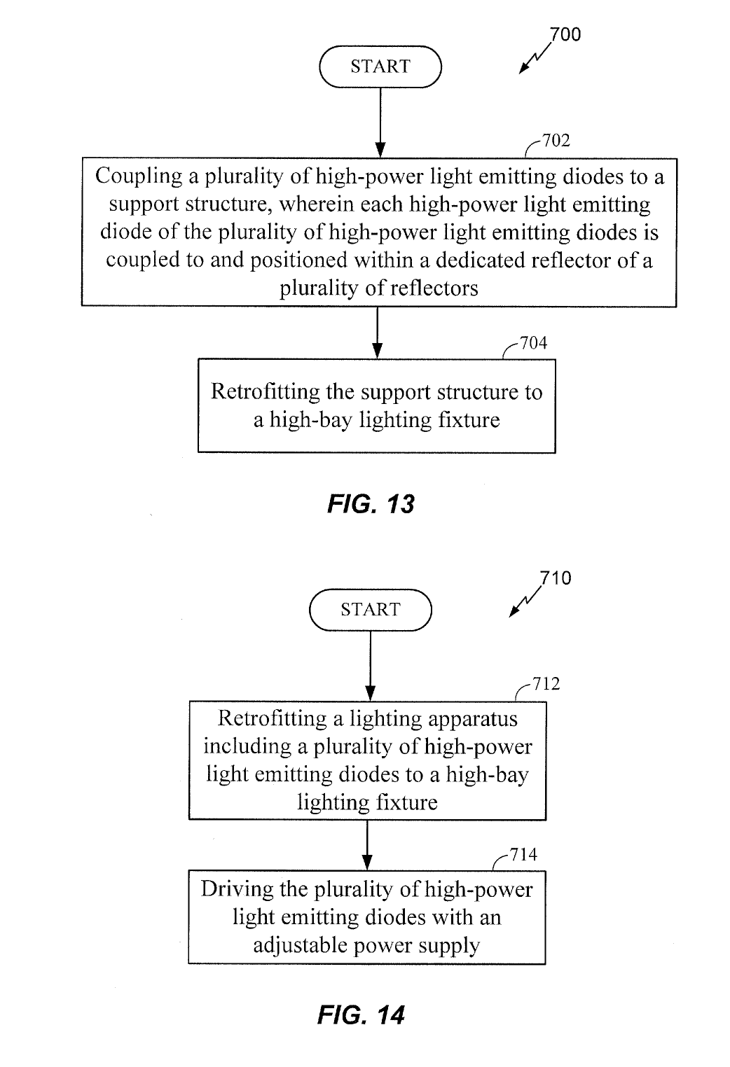

FIG. 13 is a flowchart of a method 700, in accordance with an embodiment of the present invention. Method 700 includes coupling a plurality of high-power LEDs to a support structure, wherein each high-power LED of the plurality of high-power LEDs is coupled to and positioned within a dedicated reflector of a plurality of reflectors (act 702). More specifically, for example, a plurality of LEDs 204 may be coupled to support structure 302 (see e.g., FIGS. 2-5). Method 700 further includes retrofitting the support structure to a high-bay lighting fixture (act 704). More specifically, support structure 302, having a plurality of reflectors and a plurality of LEDs coupled thereto, may be retrofit to a lighting fixture 552 (see FIG. 10).

FIG. 14 is a flowchart of another method 710, in accordance with an embodiment of the present invention. Method 710 includes retrofitting a lighting apparatus including a plurality of high-power LEDs to a high-bay lighting fixture (act 712). More specifically, for example, lighting apparatus 300 including a plurality of LEDs 204 may be coupled to lighting fixture 552 (see FIG. 10). Method 710 further includes driving the plurality of LEDs with an adjustable power supply (act 714). As an example, adjustable power supply 570 may provide power for the plurality of LEDs 204 (see FIG. 11).

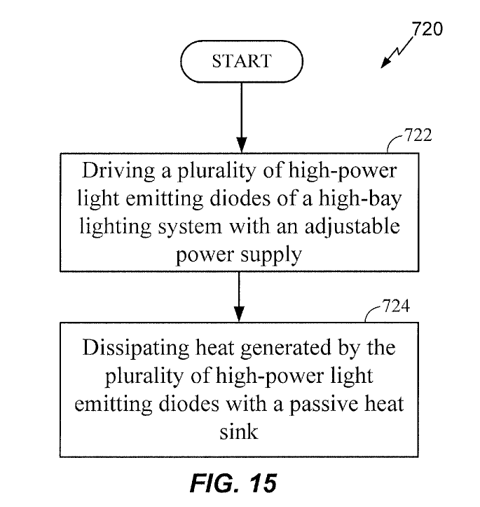

FIG. 15 is a flowchart of yet another method 720, in accordance with an embodiment of the present invention. Method 720 includes driving a plurality of high-power LEDs of a high-bay lighting system with an adjustable power supply (act 722). As an example, adjustable power supply 570 may provide power for the plurality of LEDs 204 (see FIG. 11). Method 720 further includes dissipating heat generated by the plurality of high-power LEDs with a passive heat sink (act 724). More specifically, support structure 302, which may act as a heat sink, may provide heat dissipation for a lighting system 550 (see FIG. 10).

In comparison to conventional halide lamps, the exemplary embodiments of the present invention, as described herein, may enhance high-bay lighting. As one example, embodiments of the present invention include a passive heat sink and, therefore, the devices and systems described herein may be more reliable than conventional systems, which utilize active heat sinks. Further, exemplary embodiments enable for an adjustable power level, as well as adjustable reflectors and, as a result, energy consumption may be reduced in comparison to conventional systems. As an example, exemplary embodiments of the present invention may reduce energy consumption by up to 75-80% over traditional HID technology.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. An apparatus, comprising:
a plurality of reflectors coupled to a support structure configured to be retrofit to a high-bay lighting fixture; and
a plurality of high-power light emitting diodes (LEDs), each LED of the plurality of LEDs coupled to and positioned within a dedicated reflector of the plurality of reflectors.

2. The apparatus of claim 1, the support structure comprising a heat sink.

3. The apparatus of claim 2, the heat sink comprising a passive heat sink including a plurality of holes and a plurality of fingers formed in a surface adjacent each reflector of the plurality of reflectors.

4. The apparatus of claim 1, each reflector of the plurality of reflectors comprising a base portion and a plurality of independently adjustable sides.

5. The apparatus of claim 1, each LED of the plurality of LEDs comprising a high-power LED.

6. The apparatus of claim 1, further comprising a dedicated lens cover for each reflector and associated LED.

7. The apparatus of claim 1, wherein the support structure is configured to be coupled to a lighting fixture.

8. The apparatus of claim 7, further comprising a transparent cover coupled to the lighting fixture.

9. The apparatus of claim 1, wherein the LEDs are uniformly distributed across a surface of the support structure.

10. A high-bay lighting apparatus, comprising:
a passive heat sink;
a plurality of reflectors positioned on the passive heat sink; and
a plurality of high-power light emitting diodes (LEDs), each reflector of the plurality of reflectors having an LED of the plurality of LEDs positioned thereon.

11. The apparatus of claim 10, the heat sink including a first portion, a second portion spaced from the first portion, and a plurality of stand-offs positioned between the first portion and the second portion.

12. The apparatus of claim 11, the heat sink comprising a plurality of holes and a plurality of fingers formed on each of the first portion, the second portion, and the plurality of stand-offs.

13. The apparatus of claim 10, the heat sink comprising a passive heat sink.

14. The apparatus of claim 10, each reflector having a dedicated lens coupled thereto.

15. The apparatus of claim 10, each LED of the plurality of LEDs comprising a high-power LED configured to emit more than 95 lumens per watt.

16. The apparatus of claim 10, each reflector of the plurality of reflectors comprising a base portion and plurality of adjustable sides.

17. The apparatus of claim 10, the plurality of LEDs comprising between five and fifteen LEDs.

18. A system, comprising:
a high-bay lighting fixture; and
a lighting system coupled to the high-bay lighting fixture and including:
a passive heat sink;
a plurality of reflectors positioned on the heat sink; and
a plurality of high-power light emitting diodes (LEDs), each reflector of the plurality of reflectors having an LED of the plurality of LEDs positioned thereon.

19. The system of claim 18, further comprising an adjustable power supply electrically coupled to the lighting system.

20. The system of claim 17, the lighting fixture comprising a parabolic reflector.

21. The system of claim 17, the lighting system retrofit to the lighting fixture.

22. The system of claim 17, each reflector of the plurality of reflectors comprising at least one adjustable side.

23. A method, comprising:
coupling a plurality of high-power light emitting diodes (LEDs) to a support structure, wherein each LED of the plurality of LEDs is coupled to and positioned within a dedicated reflector of a plurality of reflectors; and
retrofitting the support structure to a high-bay lighting fixture.

24. A method, comprising:
retrofitting a lighting apparatus including a plurality of high-power light emitting diodes (LEDs) to a high-bay lighting fixture; and
driving the plurality of high-power LEDs with an adjustable power supply.

25. A method, comprising:
driving a plurality of high-power light emitting diodes (LEDs) of a high-bay lighting system with an adjustable power supply; and
dissipating heat generated by the plurality of high-power LEDs with a passive heat sink.
